(19) United States
(12) Patent Application Publication
(10) Pub. No.: US 2013/0117618 A1
(43) Pub. Date: May 9, 2013

(54) SCAN TESTING OF INTEGRATED CIRCUIT WITH CLOCK GATING CELLS

(71) Applicants: HIMANSHU KUKREJA, New Delhi (IN); DEEPAK AGRAWAL, Ghaziabad (IN)

(72) Inventors: HIMANSHU KUKREJA, New Delhi (IN); DEEPAK AGRAWAL, Ghaziabad (IN)

(73) Assignee: FREESCALE SEMICONDUCTOR, INC, Austin, TX (US)

(21) Appl. No.: 13/288,037

(22) Filed: Nov. 3, 2011

(51) Int. Cl. G01R 31/28; G06F 11/22

(52) U.S. Cl. 714/726; 714/E11.148

(57) ABSTRACT

An integrated circuit includes a set of cells for operation in a functional mode and in a scan testing mode, and a spare cell. The cells are connected in a scan chain with scan data inputs connected to the outputs of preceding cells in the scan chain and respond to assertion of a scan enable signal. A clock gating element applies a functional clock signal to clock inputs of the cells in response to a gating enable signal in functional mode and a test clock signal in response to a test mode signal in scan testing mode. A functional data input of the spare cell latches the gating enable signal during the scan testing mode in response to de-assertion of the scan enable signal. The output of the spare cell is connected to the scan data input of one of the cells in response to the scan enable signal.

### BACKGROUND OF THE INVENTION

The present invention is directed to a method of scan testing clock gating cells of an integrated circuit, and to an integrated circuit having clock gating cells that can be scan tested.

Dynamic power consumption of an integrated circuit (IC) can be reduced by techniques such as frequency and voltage scaling for the active modules of the IC, and by gating (turning OFF) the clock signals for inactive modules. Clock gating cells in the clock distribution network disable the inactive modules so that the flip-flops in the inactive modules do not switch states, as switching states consumes power. When not being switched, the dynamic switching power consumption goes to zero, and only leakage currents are incurred. Clock gating works by taking the functional enable conditions attached to the modules and using these enable conditions to gate the functional clocks.

With the increase in complexity of IC devices, the complexity of testing these devices has also increased. Thus, simple connectivity testing is no longer adequate. IC devices include embedded logic circuits, each of which also needs to be tested for factors such as input and output timing compliance, frequency compliance, path delay faults, connection faults and various types of manufacturing faults. Testing of IC devices has also been complicated by involvement of multiple manufacturing firms implementing different designs, so that a common testing methodology is not practical. Further, the density of embedded logic circuits has increased rapidly over the years. This has impacted the implementation of test circuits, which need extra space on the chip. In addition, the embedded logic circuits may be surrounded by various peripheral and input/output (‘I/O’) circuits, making it difficult to include additional test circuits. Furthermore, some of the I/O terminals of the embedded logic circuits may not be accessible by test circuitry and hence cannot be tested by simple mechanisms. Moreover, multiple embedded logic circuits or multiple system on chip (‘SoC’) devices may be integrated on the same IC device, further increasing the complexity of the system. The resulting advances in test patterns and test techniques for the embedded logic circuits and the SoCs have added to the complexity of the test procedures.

Thus, it would be advantageous to extend coverage of scan tests the clock gating logic of an IC without increasing significantly the test pattern complexity.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1 is a schematic block diagram of a known electronic module in an IC with test scan chains;

FIG. 2 is a schematic block diagram of a portion of a known scan chain during scan test mode;

FIG. 3 is a schematic block diagram of a portion of another known scan chain during scan test mode;

FIG. 4 is a schematic block diagram of a portion of a scan chain during scan test mode in an integrated circuit in accordance with one embodiment of the invention, given by way of example; and

FIG. 5 is a simplified flow chart of a method of scan testing an integrated circuit in accordance with one embodiment of the invention, given by way of example.

### DETAILED DESCRIPTION OF THE INVENTION

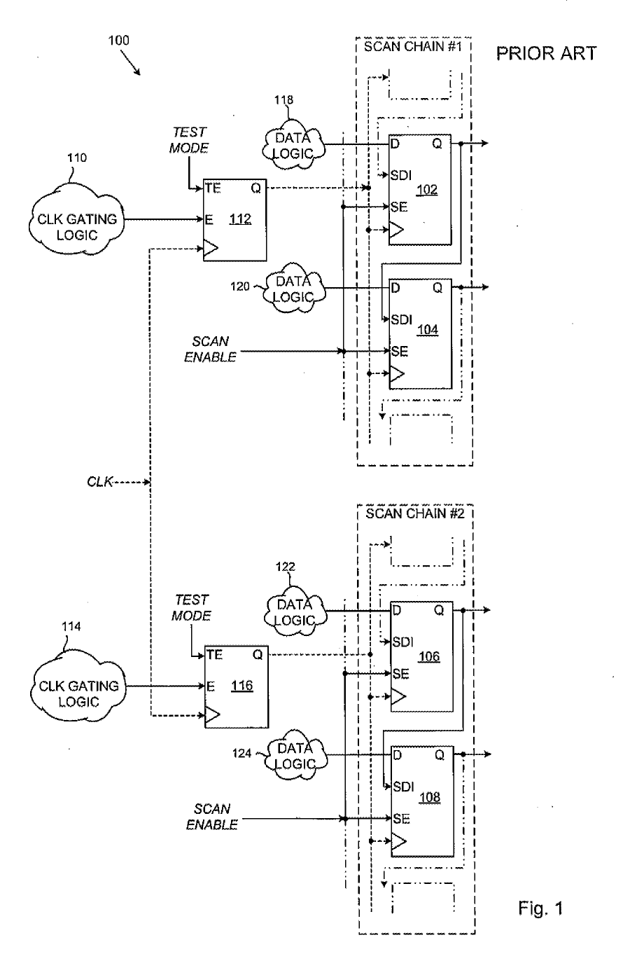

FIG. 1 illustrates an example of a typical electronic module 100 in an IC comprising output flip-flops such as 102, 104, 106 and 108, which can also be connected in a test scan chain. In this example, the flip-flops are connected in two separate scan chains SCAN CHAIN#1 and SCAN CHAIN#2. Each of the flip-flops 102-108 has a data input D, a data output Q, a scan data input SDI, a scan enable control input SE and a clock input. The SDI input of each of the flip-flops 102-108 is connected to the Q output of the previous flip-flop of the same scan chain, except for the first and last scan chain elements. The SDI input of the first scan chain element receives a test data input signal from a test access port (not shown). The output Q of the flip-flop of the last test scan chain element provides a test data output signal to the test access port. The flip-flops 102-108 receive from the test access port control signals TEST MODE and SCAN ENABLE.

The Q outputs of the flip-flops 102-108 change state in synchronism with the functional or test clock signals they receive. Clock signals CLK are generated centrally and supplied to clock inputs of clock gating latches 112, 116. In functional mode, clock gating logic 110, 114 asserts functional enable signals at E inputs of the clock gating latches 112, 116 to distribute functional clock signals selectively to the clock inputs of the desired flip-flops 102-108 according to the functional requirements. Although the same connections of the outputs of the clock gating latches 112 and 116 to all the flip-flops of the scan chain SCAN CHAIN #1 or SCAN CHAIN #2 are shown, it will be appreciated that in practice individual clock gating latches and connections to clock inputs of the flip-flops may be provided to enable individual clock gating of the functional clock signals. In scan test mode, control signals TEST MODE are asserted on test enable inputs TE of the clock gating latches 112, 116 and the clock gating latches 112, 116 supply test clock signals to the clock inputs of the flip-flops 102-108. Data processing logic modules 118, 120, 122 and 124 provide respective data signals to the individual flip-flops 102-108.

In functional mode, the control signal SCAN ENABLE is de-asserted at the control inputs SE of the active flip-flops 102-108, whose outputs Q change state in response to the data signals from the data processing logic modules 118, 120, 122 and 124 applied to their data inputs D. The outputs Q of the active flip-flops 102 to 108 change state in synchronism with the functional clock signals. The scan connections do not affect the functional operation of the flip-flops 102 to 108 and the data processing logic modules 118, 120, 122 and 124. The functional clock signals for inactive flip-flops and data processing cells are gated so that these flip-flops and cells do not change state, saving dynamic power consumption.

In scan test operation, the control signals TEST MODE set the clock gating latches 112 and 116 to receive the test clock signals, which replace the functional clock signals. The clock gating latches 112 and 116 apply the test clock signals at the appropriate periods to the relevant flip-flops that form the scan chains SCAN CHAIN #1 and SCAN CHAIN #2. The control signal SCAN ENABLE is asserted at the control inputs SE of the scan chain flip-flops to connect the outputs Q of the scan chain elements to the inputs SDI of the following flip-flop in the scan chain, forming a shift register. Test data input signals TEST IN forming a test vector applied to the SDI input of the first flip-flop of the scan chain are then shifted through the shift register in synchronization with the test clock signals, setting the outputs Q of the flip-flops 102 to 108 to a state defined by the test data input signals TEST IN. Once the test vector is correctly positioned in the scan chain, the scan chain is placed in capture mode by de-asserting the control signal SCAN ENABLE. One (or more) cycles of the test clock signals CLK are applied and propagate to the flip-flops 102, 104 and 106, 108 through the clock gating latches 112, 116 respectively. The control signal SCAN ENABLE is asserted again, the circuit returns to scan shift mode and the states of the output flip-flops TEST OUT are shifted through the scan chain by the test clock signals and recovered from the output Q of the last flip-flop of the scan chain as test results.

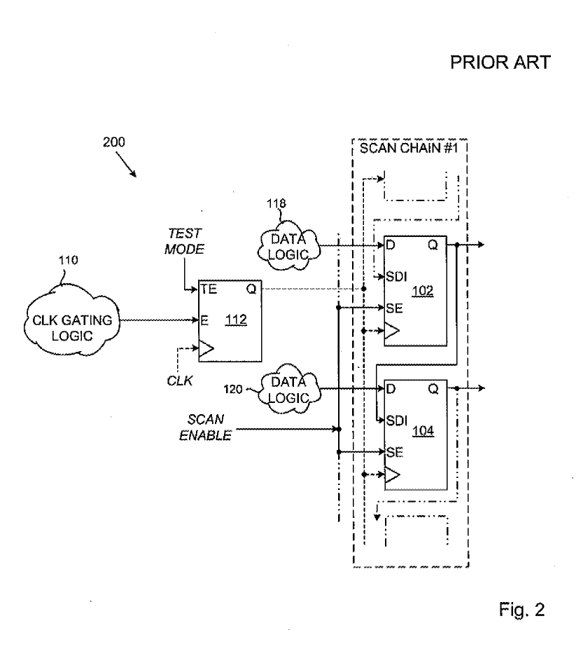

FIG. 2 illustrates a portion 200 of a known scan chain SCAN CHAIN #1 during scan test mode. The portion 200 of the scan chain SCAN CHAIN #1 comprises circuit elements 102 and 104. Each of the circuit elements 102 and 104 has a functional data input D, a scan data input SDI, a scan enable input SE and a clock input. The portion 200 of the scan chain also has an element 110 of the clock gating logic and an associated clock gating latch 112. The clock gating latch 112 has a test mode enable input TE, a functional mode enable input E, a clock input and a clock output Q. The clock gating logic element 110 has an output connected to the functional mode enable input E of the clock gating latch 112. Data processing logic modules 118 and 120 provide respective data signals to the individual flip-flops 102 and 104.

In functional mode, the control signal SCAN ENABLE at the scan enable inputs SE is de-asserted and the signals at the outputs Q of the circuit elements 102 and 104 are functions of the data signals at their functional data inputs D from the data processing logic modules 118 and 120. A control signal TEST MODE at the test mode enable input TE is de-asserted and the clock gating latch 112 applies the functional clock signal selectively to one or more of the circuit elements 102 and 104 as a function of the assertion or de-assertion of the functional enable signals at the output of the clock gating logic element 110 applied to the functional mode enable input E of the clock gating latch 112.

During the scan shift phase of the scan test operation, the control signal SCAN ENABLE at the scan enable inputs SE is asserted and the signals at the scan data inputs SDI of the circuit elements 102 and 104 are functions of the outputs Q of the preceding circuit element in the scan chain. In this known configuration, a control signal TEST MODE at the test mode enable input TE is asserted and the clock gating latch 112 applies the test clock signal to all of the circuit elements 102 and 104 in the scan chain. The control signal TEST MODE at the test mode enable input TE remains asserted during the whole of the scan test operation, including the capture phase as well as the scan shift phase. The clock gating latch 112 accordingly applies the test clock signal to the circuit elements in the scan chain for the entire scan test operation. The scan test checks the test mode enable input TE, the clock input, the clock output Q of the clock gating latch 112 and the application of the test clock to the circuit elements 102 and 104 in the scan chain. However, this configuration does not provide for the scan test to check the clock gating logic element 110 nor the functional enable signal at the input E of the clock gating latch 112. Thus, there is a gap in the coverage of the scan test.

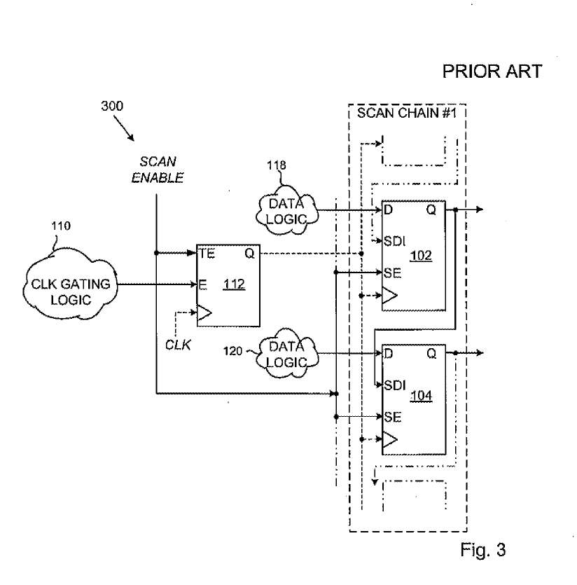

FIG. 3 illustrates a portion 300 of another known scan chain during scan test mode. Like the portion 200 of the scan chain illustrated in FIG. 2, the portion 300 of the scan chain comprises circuit elements 102 and 104. Each of the circuit elements 102 and 104 has a functional data input D, a scan data input SDI, a scan enable input SE and a clock input. The portion 300 of the scan chain includes an element 110 of the clock gating logic and an associated clock gating latch 112. The clock gating latch 112 has a test mode enable input TE, a functional mode enable input E, a clock input and a clock output Q. The clock gating logic element 110 has an output connected to the functional mode enable input E of the clock gating latch 112. Data processing logic modules 118 and 120 provide respective data signals to the individual circuit elements (flip-flops) 102 and 104.

In functional mode, the control signal SCAN ENABLE at the scan enable inputs SE is de-asserted and the signals at the outputs Q of the circuit elements 102 and 104 are functions of the data signals at their functional data inputs D from the data processing logic modules 118 and 120. A control signal SCAN ENABLE at the test mode enable input TE is de-asserted and the clock gating latch 112 applies the functional clock signal selectively to one or more of the circuit elements 102 and 104 as a function of the assertion or de-assertion of the functional enable signals at the output of the clock gating logic element 110 applied to the functional mode enable input E of the clock gating latch 112.

During the scan shift phase of the scan test operation, the control signal SCAN ENABLE at the scan enable inputs SE is asserted and the signals at the inputs SDI of the circuit elements 102 and 104 are functions of the outputs Q of the preceding circuit element in the scan chain. In this known configuration, the control signal SCAN ENABLE is also asserted at the test mode enable input TE of the clock gating latch 112 during the scan shift phase and the clock gating latch 112 applies the test clock signal to all of the circuit elements 102 and 104 in the scan chain. However, during the capture phase, the control signal SCAN ENABLE at the test mode enable input TE is de-asserted. Whether the clock gating latch 112 applies the test clock signal to the circuit elements in the scan chain during the capture phase of the scan test operation accordingly depends on the assertion or de-assertion of the signal at the output of the clock gating logic element 110 applied to the functional mode enable input E of the clock gating latch 112. The application of the test clock to the circuit elements 102 and 104 in the scan chain will accordingly not be transparent for all test patterns. Multiple test patterns must therefore be used to target the same faults, increasing the volume of test patterns. The increase in the volume of test patterns is particularly large with some scan patterns in which there are more than one capture clock.

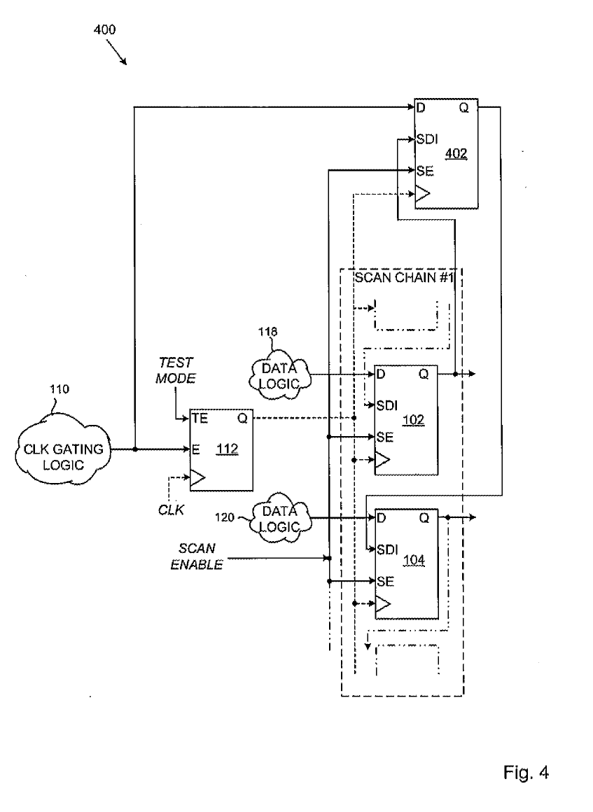

FIG. 4 illustrates an electronic module, of the kind shown and described with reference to FIG. 1, in an IC 400 in accordance with an example of one embodiment of the present invention, given by way of example. FIG. 4 shows a portion of a scan chain SCAN CHAIN#1 during scan test mode in the IC 400, which may include more than one scan chain, as described with reference to FIG. 1. The IC 400 includes a set of cells 102 and 104 (only two are shown for convenience but it is to be understood that these two are merely representative of many) for operation in functional mode and in scan testing mode, and a spare cell 402. Each of the cells 102 and 104 and the spare cell 402 has a functional data input D, a clock input, a scan data input SDI and an output Q. Data processing logic modules 118 and 120 provide respective data signals to the individual cells 102 and 104. The cells 102 and 104 and the spare cell 402 are connected in the scan chain SCAN CHAIN#1 with the scan data inputs SDI connected to the outputs Q of preceding cells in the scan chain, except for the first and last scan chain elements, in response to assertion of a control signal SCAN ENABLE applied to the SE inputs of the cells 102 and 104 and the spare cell 402. The SDI input of the first scan chain element receives a test data input signal, for example from a test access port (not shown). The output Q of the last test scan chain element provides a test data output signal, for example to the test access port.

The IC 400 also has a clock gating element for applying a functional clock signal selectively to the clock inputs of the set of cells 102 and 104 and the spare 402 in response to assertion of a gating enable signal while in functional mode. The clock gating element applies a test clock signal to the cells in response to assertion of a test clock enable signal TE in scan testing mode. The functional data input D of the spare cell 402 is connected to latch the gating enable signal during the capture phase of the scan testing mode in response to de-assertion of the control signal SCAN ENABLE applied to the SE inputs of the cells 102 and 104 and the spare cell 402, and the output Q of the spare cell 402 is connected to the scan data input SDI of one of the cells 102 and 104.

In this example, the clock gating element comprises an element 110 of the clock gating logic and an associated clock gating latch 112 and the gating enable signal is the output signal of the clock gating element 110. The clock gating latch 112 has a test mode enable input TE, a functional mode enable input E, a clock input and a clock output Q. The clock gating logic element 110 has an output connected to the functional mode enable input E of the clock gating latch 112. However, it will be appreciated that other structures are available.

In one example of the IC 400, the spare cell 402 is not operational to capture data in the functional mode and is a redundant cell provided in case re-work of the IC is necessary after testing the IC, but which has not been used for re-work, at least yet.

In this example of the IC 400, the control signal SCAN ENABLE is asserted during scan shift phases of the scan testing mode and is de-asserted during a capture phase of the scan testing mode. A signal representative of operation of the clock gating element 110, 112 and of the gating enable signal is captured at the functional data input D of the spare cell 402 during the capture phase of the scan testing mode, and is applied to the scan data input SDI of one of the cells 102 and 104 of the set during the scan shift phase of the scan testing mode.

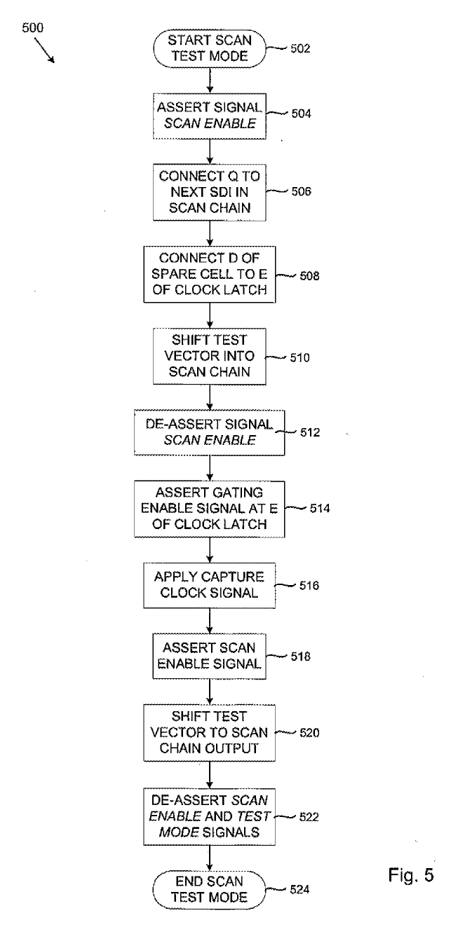

FIG. 5 illustrates a method 500 of testing an IC in accordance with an example of one embodiment of the present invention, given by way of example. The method 500 is applicable to testing an IC, such as the IC 400, including a set of cells 102 and 104 for operation in functional mode and in scan testing mode, a spare cell 402 and a clock gating element for applying a functional clock signal selectively to the cells in response to assertion of a gating enable signal during the operation in functional mode. In functional mode, the control signal SCAN ENABLE at the scan enable inputs SE is de-asserted and the signals at the outputs Q of the circuit elements 102 and 104 and the spare cell 402 are functions of the data signals at their functional data inputs D from data processing logic modules 118 and 120.

In scan testing mode, the clock gating element applies a test clock signal to the cells in response to assertion of a control signal TEST MODE. Each of the cells 102 and 104 and the spare cell 402 has a functional data input D, a clock input, a scan data input SDI and an output Q. The method of testing comprises connecting the cells 102 and 104 and the spare cell 402 in a scan chain with the scan data inputs SDI connected to the outputs Q of preceding cells in the scan chain in response to assertion of a scan enable signal SE. The functional data input D of the spare cell 402 is connected to receive the gating enable signal during the scan testing mode in response to de-assertion of the scan enable signal SE. The output Q of the spare cell 402 is connected to the scan data input SDI of one of the cells 102 and 104 of the set in response to assertion of the scan enable signal SE.

In more detail, the method 500 of scan testing the IC 400, for example, starts at 502. The control signal SCAN ENABLE is asserted at 504 and the cells 102 and 104 and the spare cell 402 are connected in a scan chain with the scan data inputs SDI connected to the outputs Q of preceding cells in the scan chain at 506. The functional data input D of the spare cell 402 is connected physically to the clock gating element to receive the gating enable signal at 508. A test vector is shifted into the scan chain at 510. The control signal SCAN ENABLE is de-asserted at 512. The gating enable signal is asserted at the E input of the clock gating element at 514 and one or more cycles of capture clock signal are applied at 516, so that the spare cell 402 captures a signal representative of the operation of the clock gating element and of the gating enable signal while the set of cells 102 and 104 capture the signals at their data inputs D from the data logic 118 and 120. The control signal SCAN ENABLE is asserted again at 518 and the outputs of the cells 102 and 104 and the spare cell 402 are shifted through the scan chain to recover the test results at the scan chain output at 520. The control signals SCAN ENABLE and TEST MODE are de-asserted at 522 and the scan test mode terminates at 522.

In operation of the IC 400 and in the method 500, the control signal TEST MODE at the test mode enable input TE remains asserted during for the entire scan test operation, including the capture phase as well as the scan shift phase. The clock gating latch 112 applies the test clock signal to the cells 102 and 104 and the spare cell 402 in the scan chain for the entire scan test operation. The scan test checks the data logic 118 and 120. In addition, the scan test also checks the clock gating logic element 110 since the gating enable signal is representative of operation of the clock gating element 110, is captured by the spare cell 402 during the capture phase of the scan testing mode, and is applied in the scan chain. Accordingly the coverage of the scan test includes the clock gating logic element 110. In a practical example of implementation, the IC 400 had a test coverage of 98.2%, where the IC 200 had a test coverage of 97.0%, thus the gap in coverage was reduced by 1.2%.

Moreover, during the whole of the scan test mode, even during the capture phase, the control signal TEST MODE at the test mode enable input TE is asserted. The clock gating latch 112 applies the test clock signal to the circuit elements in the scan chain during the capture phase of the scan test operation irrespective of the state of the signal at the gating enable input E of the clock gating latch 112. The application of the test clock to the circuit elements 102 and 104 in the scan chain is accordingly transparent for all test patterns, avoiding the need for multiple test patterns to target the same faults. In a practical example of implementation, the IC 400 had a scan pattern volume of 7,300, where the IC 300 had a scan pattern volume of 10,390 for equivalent coverage, representing a reduction in scan pattern volume of nearly 30%.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate circuit elements or devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice-versa. Also, a plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals. Also, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. Further, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Those skilled in the art also will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, the examples, or portions thereof, may be implemented as soft or code representations of physical circuitry or of logical representations convertible into physical circuitry, such as in a hardware description language of any appropriate type. However, other modifications, variations and alternatives are also possible. The specifications and drawings are, therefore, to be regarded in an illustrative rather than in a restrictive sense.

In the claims, the terms “a” or “an,” mean one or more than one. The use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe and are not necessarily intended to indicate temporal or other prioritization of such elements. The fact that certain measures are recited in mutually different claims does not indicate that a combination of these measures cannot be used to advantage.

1. An integrated circuit (IC) including a set of cells for operation in a functional mode and in a scan testing mode, and a spare cell, each of said cells of said set of cells and said spare cell having a functional data input, a clock input, a scan data input and an output, and each of said cells of said set of cells and said spare cell being connected in a scan chain with said scan data inputs connected to said outputs of preceding cells in said scan chain in response to assertion of a scan enable signal, said IC comprising:
a clock gating element for applying a functional clock signal selectively to said clock inputs of said cells in said scan chain in response to assertion of a gating enable signal during said operation in functional mode and for applying a test clock signal to said cells in said scan chain in response to assertion of a test mode signal in scan testing mode; and
said functional data input of said spare cell being connected to latch said gating enable signal during said scan testing mode in response to de-assertion of said scan enable signal, and said output of said spare cell being connected to said scan data input of one of said cells of said set in response to assertion of said scan enable signal.

2. The integrated circuit of claim 1, wherein said spare cell is not operational in said functional mode and is a redundant cell for re-work.

3. The integrated circuit of claim 1, wherein said scan enable signal is asserted during scan shift phases of said scan testing mode and is de-asserted during a capture phase of said scan testing mode.

4. The integrated circuit of claim 3, wherein said gating enable signal is captured at said functional data input of said spare cell during said capture phase of said scan testing mode, and is applied to said scan data input of one of said cells of said set during said scan shift phase of said scan testing mode.

5. A method of scan testing an integrated circuit (IC), the IC including a set of cells for operation in a functional mode and a scan testing mode, a spare cell, and a clock gating element for applying a functional clock signal selectively to each of said cells of said set of cells and said spare cell in response to assertion of a gating enable signal during said operation in the functional mode and for applying a test clock signal to each of said cells of said set of cells and said spare cell in response to assertion of a test mode signal in the scan testing mode, wherein each of said cells of said set of cells and said spare cell having a functional data input, a clock input, a scan data input and an output, the method comprising:
connecting said cells of said set of cells and said spare cell in a scan chain with said scan data inputs connected to said outputs of preceding cells in said scan chain in response to assertion of a scan enable signal; and
connecting said functional data input of said spare cell to latch said gating enable signal during said scan testing mode in response to de-assertion of said scan enable signal, and connecting said output of said spare cell to said scan data input of one of said cells of said set of cells in response to assertion of said scan enable signal.

6. The method of claim 5, further comprising asserting said scan enable signal during scan shift phases of said scan testing mode and de-asserting said scan enable signal during a capture phase of said scan testing mode.

7. The method of claim 6, further comprising:
capturing a signal representative of operation of said clock gating element and said gating enable signal at said functional data input of said spare cell during said capture phase of said scan testing mode; and
applying said captured signal to said scan data input of one of said cells of said set during said scan shift phase of said scan testing mode.
